(19) United States
(12) Patent Application Publication
(10) Pub. No.: US 2026/0100218 A1
(43) Pub. Date: Apr. 9, 2026

(54) APPARATUS FOR DATA READ TIMING CALIBRATION IN STACKED MEMORY

(71) Applicant: MICRON TECHNOLOGY, INC., BOISE, ID (US)

(72) Inventors: Jaeil Kim, Boise, ID (US); Nicole Kang, Boise, ID (US); Vijayakrishna Vankayala, Boise, ID (US); Jason M. Brown, Boise, ID (US)

(73) Assignee: MICRON TECHNOLOGY, INC., BOISE, ID (US)

(21) Appl. No.: 19/347,543

(22) Filed: Oct. 1, 2025

Related U.S. Application Data
(60) Provisional application No. 63/704,918, filed on Oct. 8, 2024.

(51) Int. Cl. G11C 11/4076; G11C 11/4096

(52) U.S. Cl. CPC G11C 11/4076; G11C 11/4096; G11C 2207/2254

(57) ABSTRACT

Embodiments of the disclosure provide an apparatus comprising a plurality of through-silicon vias (TSVs), a plurality of core dies, and a calibration circuit. The core dies are stacked with one another, and each core die outputs read data to one or more assigned TSVs of the plurality of TSVs in response to a read enable signal. The calibration circuit compares data read timings of the core dies to determine a slowest core die, and adds a delay to the read enable signal of at least one of the core dies other than the slowest core die to cause the data read timing of the at least one of the core dies match the data read timing of the slowest core die.

### CROSS-REFERENCE TO RELATED APPLICATIONS

This application claims the filing benefit of U.S. Provisional Application No. 63/704,918, filed October 8, 2024. This application is incorporated by reference herein in its entirety and for all purposes.

### BACKGROUND

High data reliability, high speed memory access, lower power consumption, and reduced chip size are features that are demanded from semiconductor memory devices, such as a dynamic random-access memory (DRAM). A memory device may be a three-dimensional stacked (3DS) memory device or a 3DS-type memory device, in which a number of core dies, each containing a memory array, are stacked on each other. In one case, the bottom core die may take a role of an interface as a master chip, and the upper core dies may receive control information from the master chip as slave chips. In another case, the core dies may be stacked on an interface die, and receive control information from the interface die. The bottom core die or the interface die may have terminals coupled to one or more external devices for external communication. The dies may be coupled by through silicon vias (TSVs) to communicate with one another. Data may be transmitted along one or more TSV data paths from or to the dies. For example, during a read operation, data read from a memory array of a selected core die is transmitted to the bottom die or the interface die along a designated TSV data path. Since the dies may be provided from different wafers or may have different fabrication processes and conditions, data read timings may vary and may require calibration.

### BRIEF DESCRIPTION OF THE DRAWINGS

FIG. 1 is a block diagram of an example semiconductor device according to some embodiments of the disclosure.

FIG. 2A is a schematic diagram of at least part of an example memory device in a perspective view according to some embodiments of the disclosure.

FIG. 2B is a block diagram of at least part of a core die of an example memory device according to some embodiments of the disclosure.

FIG. 3 depicts example data read time windows according to some embodiments of the disclosure.

FIG. 4. depicts example data read timings according to some embodiments of the disclosure.

FIG. 5 is a flow chart of example data read timing calibration according to some embodiments of the disclosure.

FIGS. 6 and 7 each are a timing diagram of various signals in example data read timing calibration according to some embodiments of the disclosure.

FIG. 8 is a schematic diagram of example calibration command distribution according to some embodiments of the disclosure.

FIG. 9 is a schematic diagram of example TSV allocation according to some embodiments of the disclosure.

FIG. 10 is a schematic diagram of an example apparatus according to some embodiments of the disclosure.

FIG. 11 is a schematic diagram of an example apparatus according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

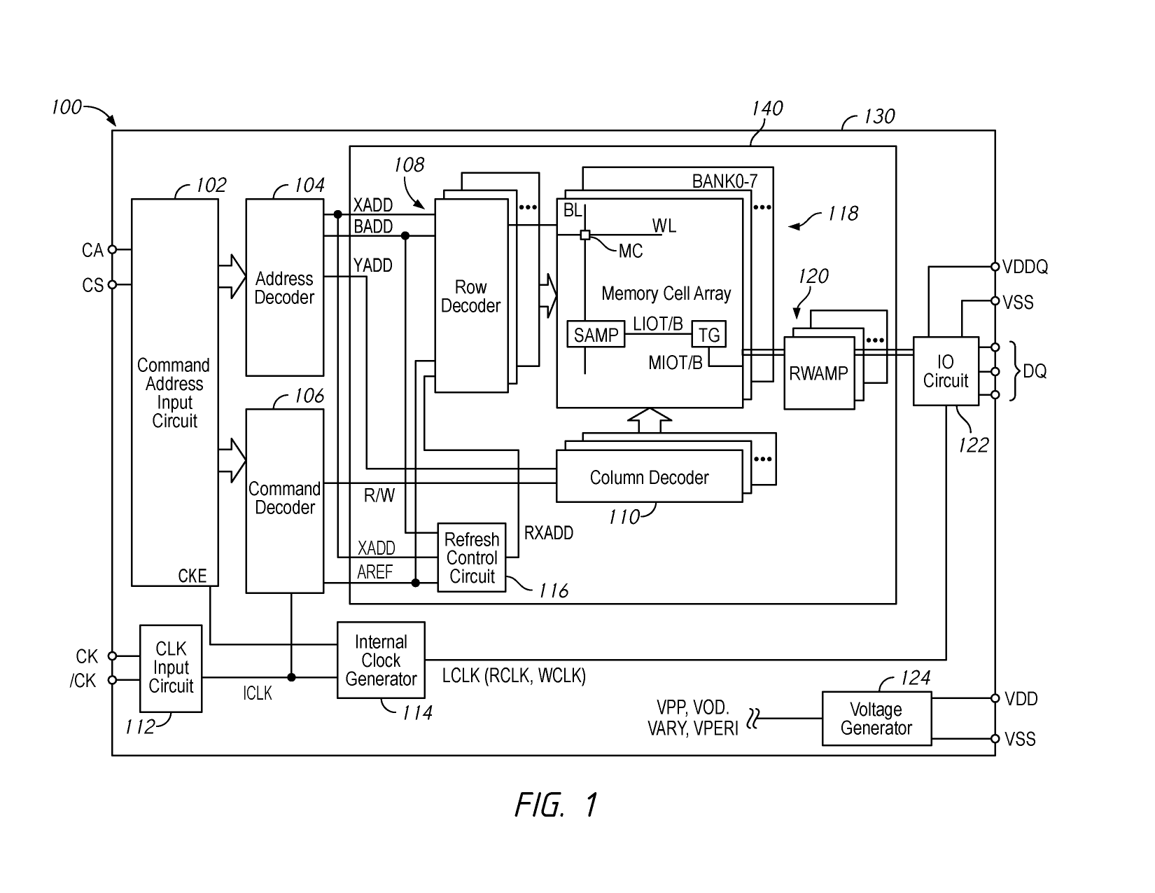

FIG. 1 is a block diagram of an example semiconductor device 100 according to some embodiments of the disclosure. The semiconductor device 100 may be a semiconductor memory device, such as a dynamic random-access memory (DRAM) device. The DRAM device may include an interface die and a plurality of core dies which are stacked on the interface die. In the example diagram of FIG. 1, certain components are shown located on an interface (IF) die 130, while other components are shown as part of each of core dies 140. For the sake of clarity, only a single core die 140 and its components are shown; however, there may be multiple core dies (e.g., 2, 4, 6, 8, 16, or more) each with similar components to each other. The example semiconductor device 100 of FIG. 1 shows a particular arrangement of components between the IF die 130 and the core die 140; however, other arrangements may be used in other embodiments. For example, a refresh control circuit 116 may be on the IF die 130 in some embodiments. For the sake of illustration, the core die 140 is drawn as a rectangular box which is smaller than the IF 130; however, the core die 140 and IF die 130 may have any size relationship to each other. For example, the core die 140 and IF die 130 may be approximately the same size. The IF die 130 may include or may be part of a logic die. In other embodiments, the bottom core die of the stacked core dies may take a role of an interface as a master chip, and the upper core dies may act as slave chips to receive control information from and transmit data to the bottom core die.

The semiconductor device 100 includes a memory array 118 on each of the core dies 140. The memory array 118 is shown as including a plurality of memory banks. In the embodiments of FIG. 1, the memory array 118 is shown as including eight memory banks BANK0-BANK7. More or fewer banks may be included in the memory array 118 of other embodiments. Each memory bank includes a plurality of word lines WL, a plurality of bit lines BL, and a plurality of memory cells MC arranged at intersections of the plurality of word lines WL and the plurality of bit line BL. Selection of the word line WL is performed by a row decoder 108 and selection of the bit lines BL is performed by a column decoder 110, each of which may also be located on each of the core dies 140. In the embodiments of FIG. 1, the row decoder 108 includes a respective row decoder for each memory bank and the column decoder 110 includes a respective column decoder for each memory bank. The bit lines BL are coupled to a respective sense amplifier (SAMP) of the memory array 118. Read data from the bit line BL is amplified by the sense amplifier SAMP, and transferred to read/write amplifiers (RWAMPs) 120 over complementary local data lines (LIOT/B), transfer gate (TG), and complementary main data lines (MIOT/B) which are coupled to RWAMP 120. Conversely, write data outputted from RWAMP 120 is transferred to the sense amplifier SAMP over the complementary main data lines MIOT/B, the transfer gate TG, and the complementary local data lines LIOT/B, and written in the memory cell MC coupled to the bit line BL.

The semiconductor device 100 may employ a plurality of external terminals located on the IF die 130 or the bottom core die. The external terminals may include command and address (CA) terminals coupled to a command and address bus to receive commands and addresses and a chip select (CS) signal, clock terminals to receive clocks CK and /CK, data terminals DQ to provide data, and power supply terminals to receive power supply potentials VDD, VSS, and VDDQ.

The clock terminals are supplied with external clocks CK and /CK that are provided to an input circuit 112. The external clocks CK and /CK may be complementary. The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal clocks LCLK are provided to an input and output (IO) circuit 122 to time operation of circuits included in the IO circuit 122, for example, to data receivers to time the receipt of write data.

The internal clocks LCLK may include a read clock (RCLK) which is used to control the timing of read operations, and a write clock (WCLK) which is used to control the timing of write operations. The internal clocks may be passed to the IO circuit 122. In some instances, the internal clocks may also be passed to internal components, such as RWAMP 120, of the core die 140.

The CA terminals may be supplied with memory addresses. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The semiconductor device 100 may receive an access command which is a read command. When a read command is received, and a bank address, a row address and a column address are timely supplied with an activate command and the read command, read data is read from memory cells in the memory array 118 corresponding to the row address and column address. The read command is received by the command decoder 106, which provides internal commands so that the read data from the memory cells in the memory array 118 is provided to RWAMP 120. The read data is output to outside the semiconductor device 100 from the data terminals DQ via the IO circuit 122.

The semiconductor device 100 may receive an access command which is a write command. When the write command is received, and a bank address, a row address and a column address are timely supplied with an activate command and the write command, write data is supplied through the DQ terminals to RWAMP 120. The write data supplied to the data terminals DQ is written to the memory cells in the memory array 118 corresponding to the row address and column address. The write command is received by the command decoder 106, which provides internal commands so that the write data is received by data receivers in the IO circuit 122. Write clocks may also be provided to the external clock terminals for timing the receipt of the write data by the data receivers of the IO circuit 122. The write data is supplied via the IO circuit 122 to RWAMP 120.

The semiconductor device 100 may also receive commands causing it to carry out one or more refresh operations as part of a self-refresh mode. In some embodiments, the self-refresh mode command may be externally issued to the semiconductor device 100. In some embodiments, the self-refresh mode command may be periodically generated by a component of the device. In some embodiments, when an external signal indicates a self-refresh entry command, the refresh signal AREF may also be activated.

The power supply terminals are supplied with power supply potentials VDD and VSS. The power supply potentials VDD and VSS are supplied to an internal voltage generator circuit 124. The internal voltage generator circuit 124 generates various internal potentials such as VPP, VOD, VARY, VPERI, and the like based on the power supply potentials VDD and VSS.

The power supply terminals are also supplied with power supply potential VDDQ. The power supply potential VDDQ is supplied to the IO circuit 122. The power supply potential VDDQ may be the same potentials as the power supply potential VDD in one instance. The power supply potential VDDQ may be different potentials from the power supply potential VDD in another instance. The power supply potential VDDQ are used for the IO circuit 122 so that power supply noise generated by the IO circuit 122 does not propagate to the other circuit blocks.

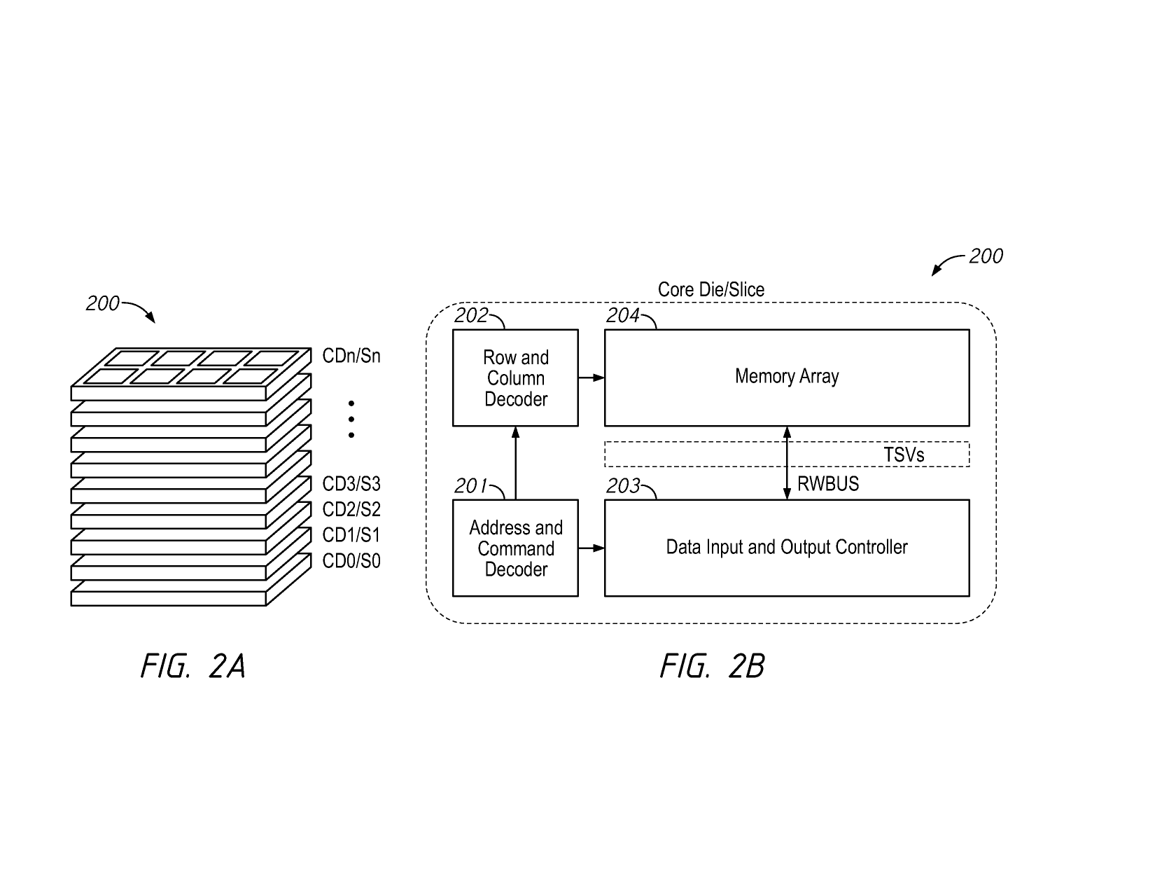

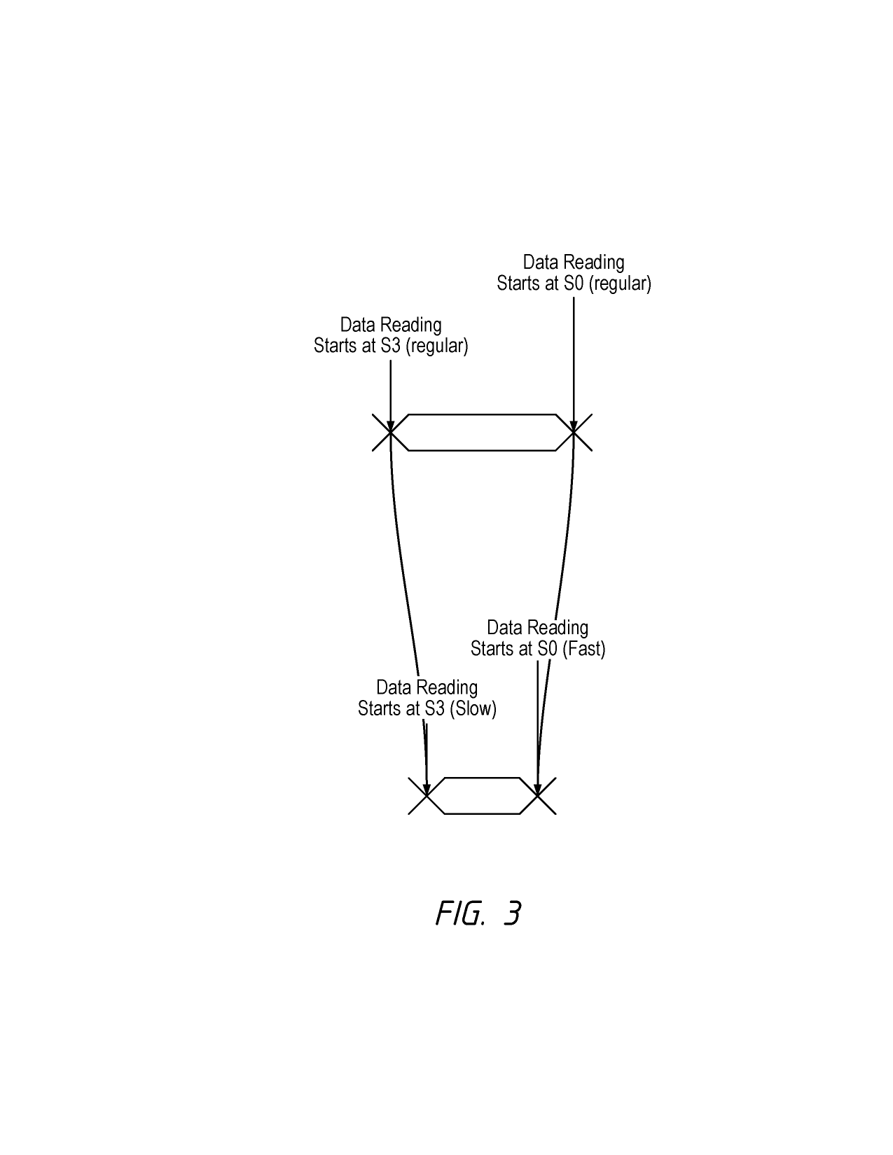

FIG. 2A is a schematic diagram of at least part of an example memory device 200 in a perspective view according to some embodiments of the disclosure. FIG. 2B is a block diagram of at least part of an example core die of the memory device 200 according to some embodiments of the disclosure. The memory device 200 may be a stacked memory device. The memory device 200 includes a plurality of core dies CD0-CDn (where n is an integer) stacked with one another. The core dies may also be referred to as slices S0-Sn (where n is an integer).

The stacked core dies CDs may be coupled with each other by a plurality of through-silicon vias (TSVs) for data and signal transmission. TSVs may penetrate through the stacked core dies CDs in a die stacking direction or a vertical direction in the drawing. Each core die CD may include a memory array for storing data and further include circuits for performing memory operations, such as read and write operations. Each core die CD in the illustrated example includes an address and command decoder 201, a row and column decoder 202, a data input and output controller 203, and a memory array 204. The bottom core die CD0 may serve as a master chip and may include terminals or pads coupled to external devices for external communication. The upper core dies CD1-CDn may serve as slave chips and communicate with the bottom core die CD0 using TSVs. For example, CD0 send control information to and receive read data from CD1-CDn. TSVs may be arranged in the area between the memory array 204 and the data input and output controller 203.

The address and command decoder 201 may generate and output row and column address signals and row and column command signals to the row and column decoder 202. The address and command decoder 201 may also supply a core die or slice select signal and various enable clock signals to the data input and output controller 203. The core die/slice select signal may include a core die/slice address. The data input and output controller 203 sends and receives the data to and from the memory array 204 through a read and write bus (RWBUS) for data read and write operations. RWBUS may include a plurality of RWBUSs as data transfer wirings. The memory array 204 may include a plurality of memory banks. Each memory bank may include a plurality of word lines, a plurality of bit lines, and a plurality of memory cells arranged at intersections of the word lines and the bit lines. The row and column decoder 202 decodes and obtains row and column commands and addresses based on the signals received from the address and command decoder 201 for the data read and write operations at specific memory banks or memory cells in response to the decoded commands and addresses. In the example memory device 200, each core die may also include a calibration circuit (not separately depicted) to calibrate data read timings of the stacked core dies CD-CDn (slices S0-Sn). In other instances, the calibration circuit may be included in external devices coupled to the bottom core die CD0. In still other instances, the bottom die CD0 may be replaced with an interface die.

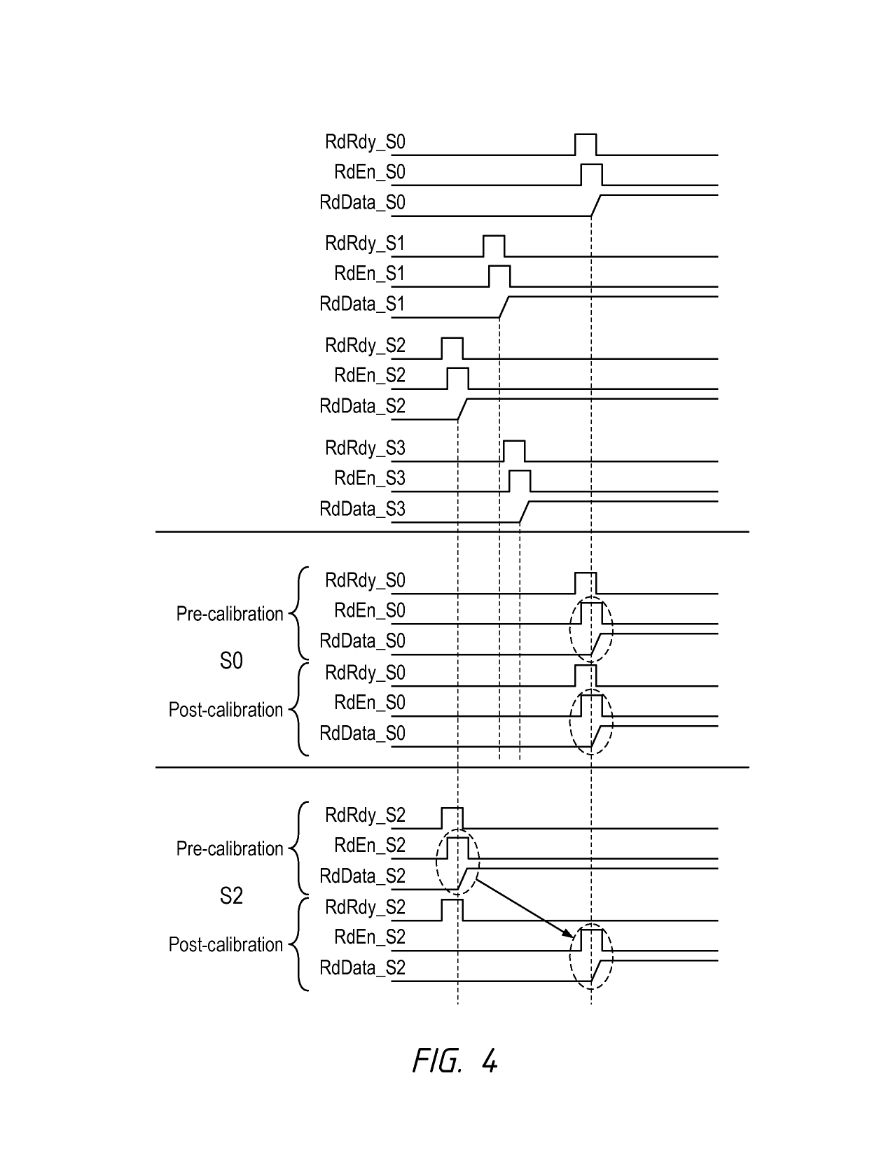

FIG. 3 depicts example data read time windows of the stacked slices according to some embodiments of the disclosure. The stacked slices may be provided from different wafers or may have different fabrication processes and conditions, which may cause, for example, transistors formed in the slices vary in statuses and characteristics. The data read time windows of the respective slices may then differ from each other. One read time window may be narrower than another read time window. Such time window may not be sufficient to capture the data. For example, if slice S3 and slice S0 have a slower data read timing and a faster data read timing than the expected regular timing, respectively, then the data reading in slice S3 starts late whereas the data reading in slice S0 starts early. This leads to the narrower time window than the regular time window as compared in FIG. 3, which may result in an insufficient time duration for reading data from slice S3.

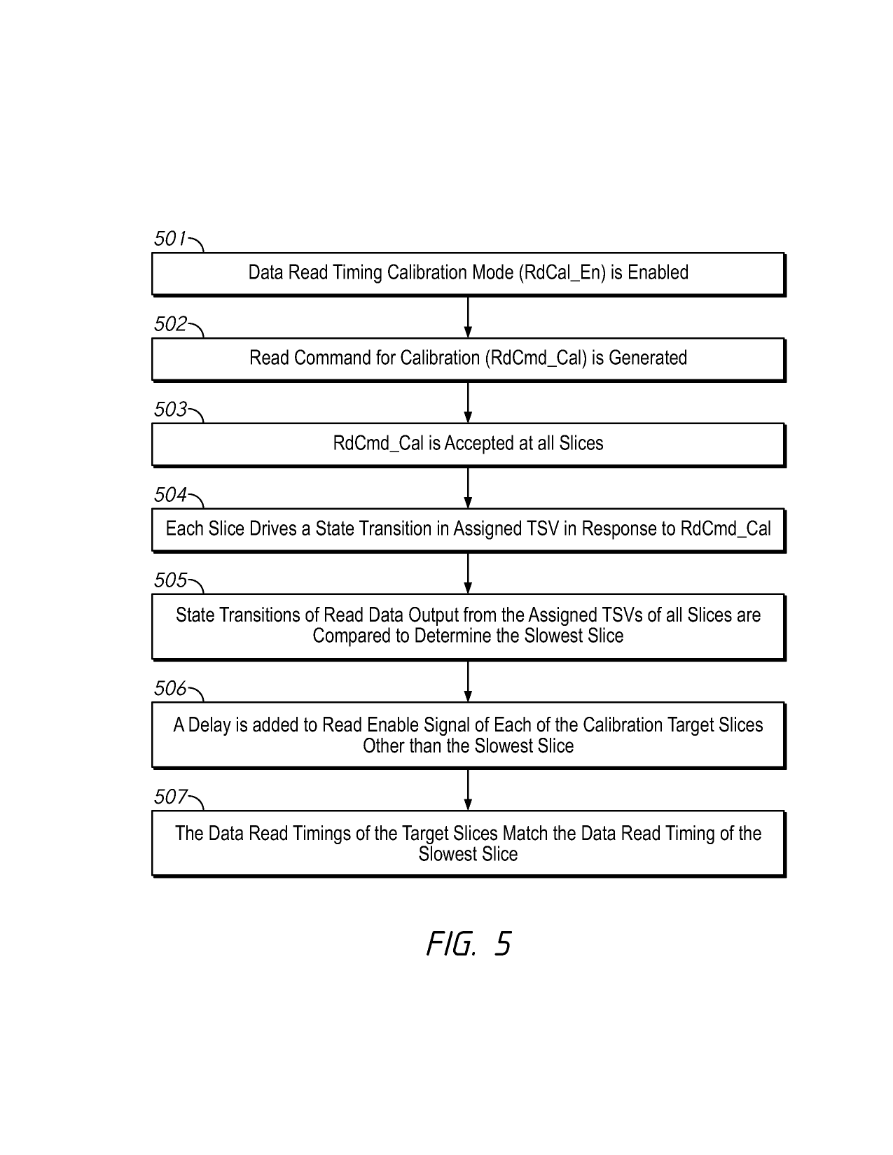

FIG. 4 depicts example data read timings of the stacked slices according to some embodiments of the disclosure. Each of the stacked slices S0-S3 receives a read ready signal RdRdy, based on which a read enable signal RdEn is generated, and starts the data reading in response to the read enable signal RdEn. The data read from the memory array RdData is passed along TSVs to the bottom slice of the stacked slices where external terminals are provided for communication with external devices. The read ready signal RdRdy may be generated based on a read command supplied from external devices. The read ready signal RdRdy may be included in the read command. The slices may be selected based on a slice select signal. The slice select signal may include a slice address. The slice select signal may be included in the read command. The TSVs may be selected based on a TSV select signal. As described above, each slice may have a different read timing. In the depicted example, slice S0 has the slowest read timing whereas slice S2 has the fastest read timing. In such a case, for example, the read timings of slices S1, S2, and S3 may be calibrated to match the read timing of slice S0. The calibration may be performed by delaying the read timings of slices S1, S2, and S3 as far as the read timing of slice S0. For example, the read enable signal of slice S2 (RdEn_S2) is delayed to align with the read enable signal of slice S0 (RdEn_S0), and hence the read timings match between slices S0 and S2. Likewise, the calibration is performed to S1 and S3 so that their read timings match the read timing of slice S0. The read timing of slice S0 stays the same before and after the calibration. Accordingly, the data read timings and hence the data read time windows are aligned for all stacked slices S0-S3.

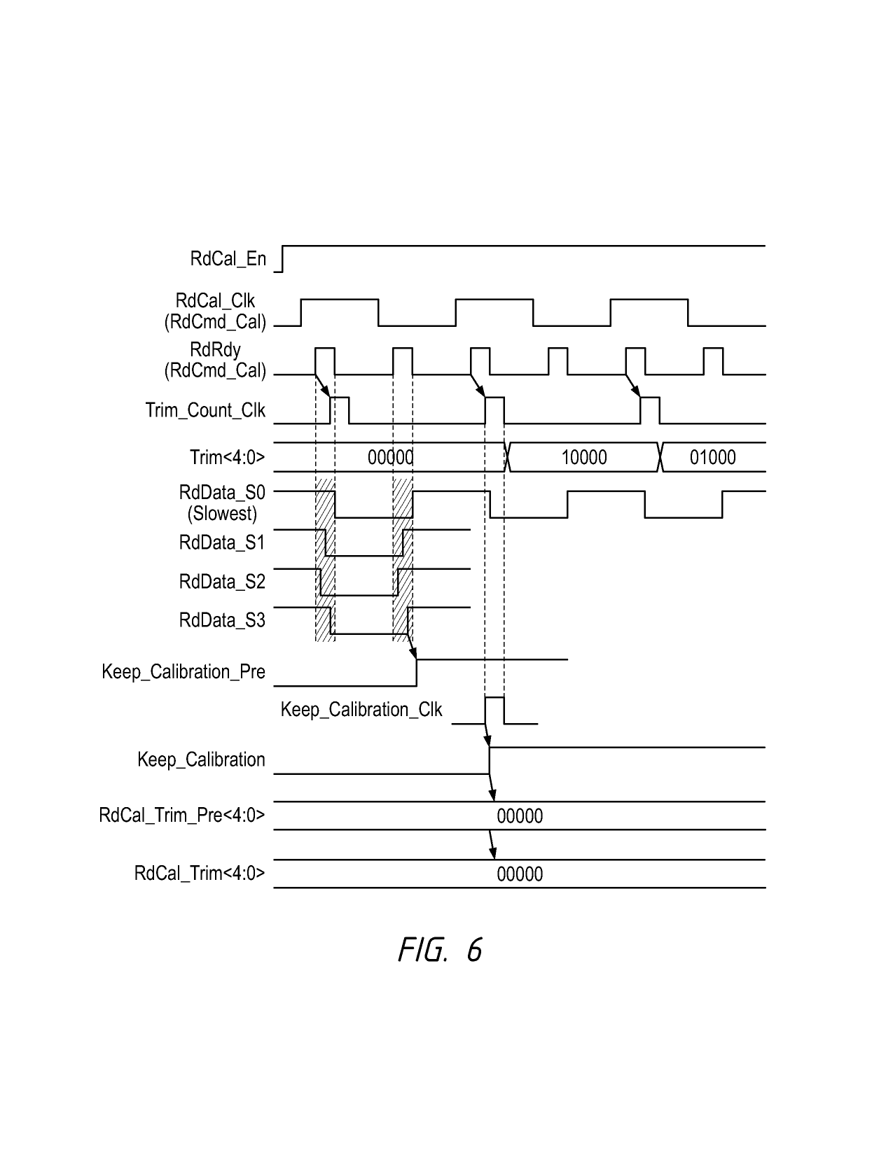

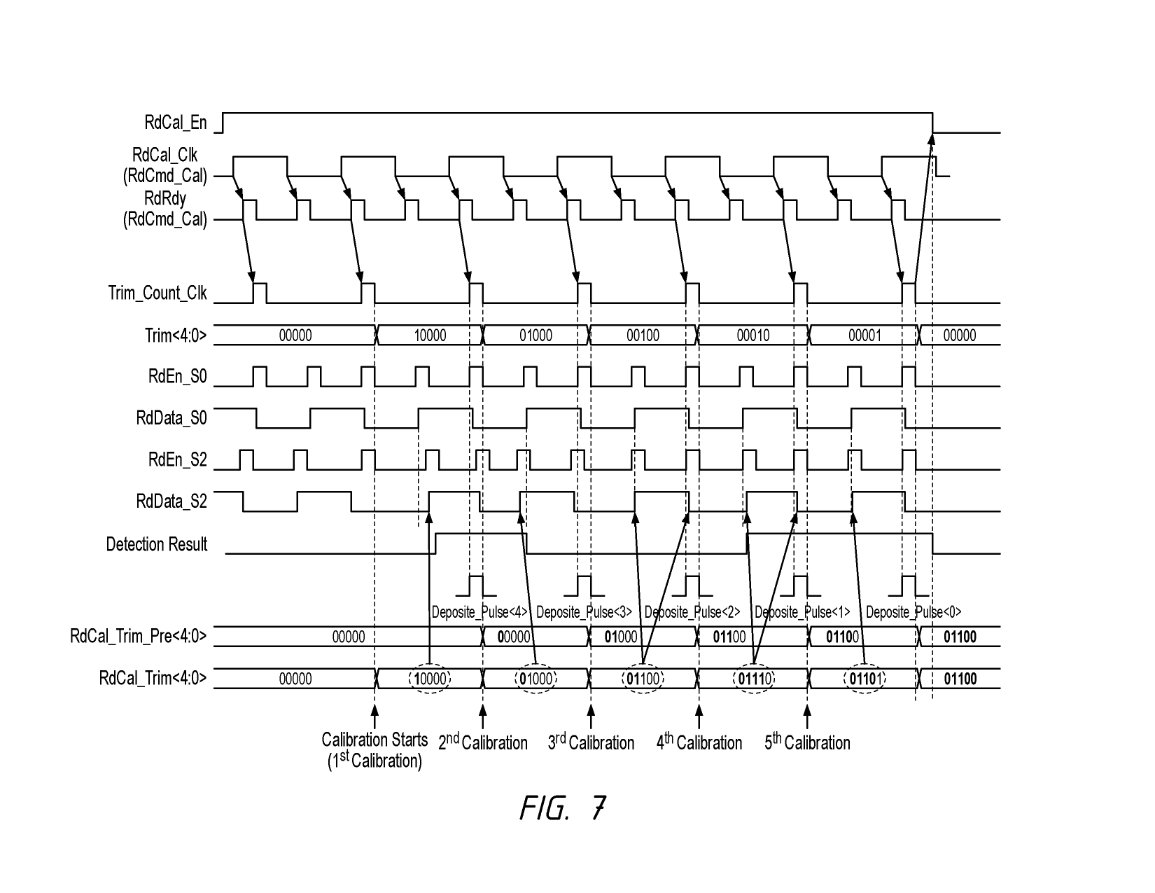

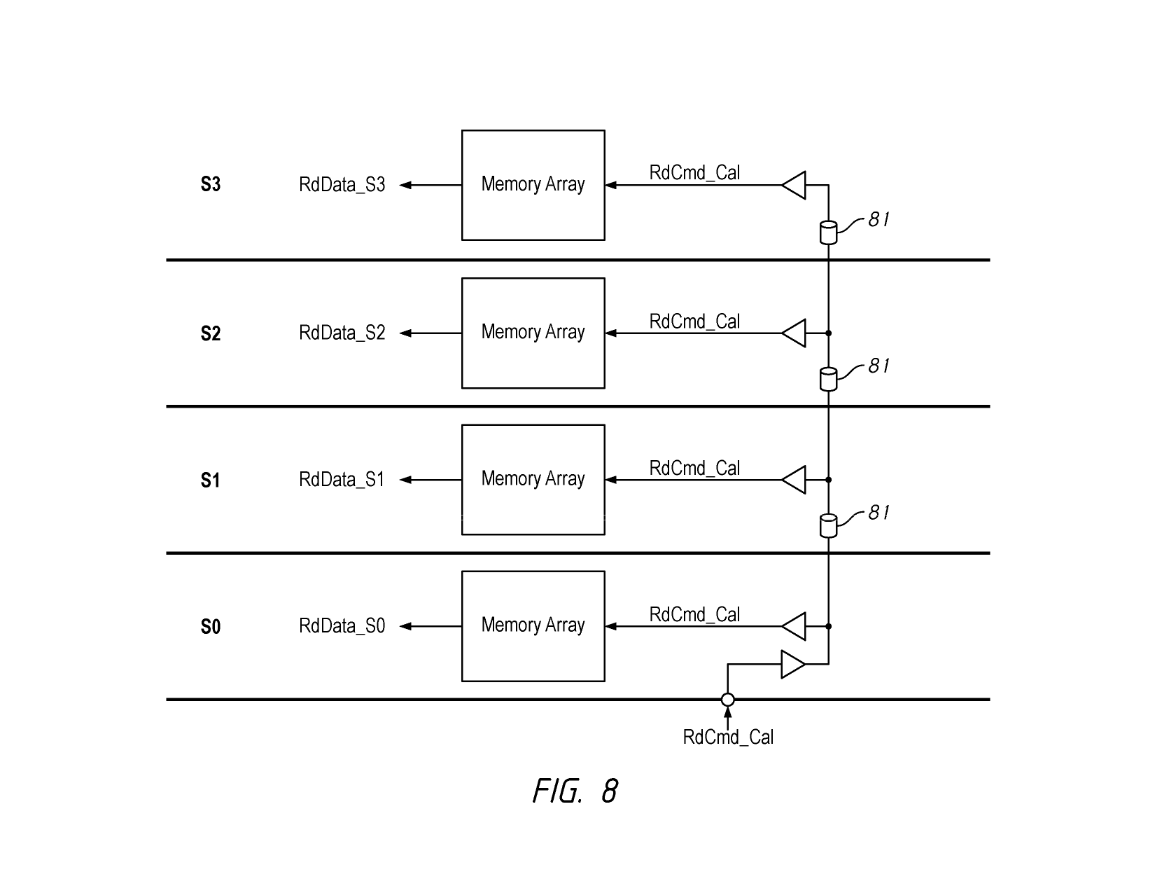

FIG. 5 is a flow chart of example data read timing calibration according to some embodiments of the disclosure. FIGS. 6 and 7 each are a timing diagram of various signals in example data read timing calibration according to some embodiments of the disclosure. When a data read timing calibration mode (RdCal_En in FIG. 6) is enabled at, for example, powerup or initialization (501 in FIG. 5), a read command for calibration (RdCmd_Cal in FIG. 6) is generated by, for example, external devices (502 in FIG. 5). RdCmd_Cal is then accepted at all slices (503 in FIG. 5). RdCmd_Cal may include a read calibration clock RdCal_Clk and a read ready signal RdRdy (see FIG. 6) synced to RdCal_Clk. RdCal_En triggers RdCal_Clk to toggle, and at rising and falling edges of RdCal_Clk, RdRdy is generated. FIG. 8 is a schematic diagram of example calibration command distribution according to some embodiments of the disclosure. In the depicted example, the bottom slice S0 of the stacked slices S0-S3 receives RdCmd_Cal at its external terminals from external devices. RdCmd_Cal is then passed to the upper slices S1-S3 along TSVs 81. In the normal operation, only selected one of the upper slices S1-S3 may accept a read command from the bottom slice S0 at a time. In the read timing calibration mode, all of the upper slices S1-S3 may accept the read command generated for the calibration at once. RdCmd_Cal then triggers the read operation to output the read data RdData_S0-S3 from the memory arrays in the respective slices.

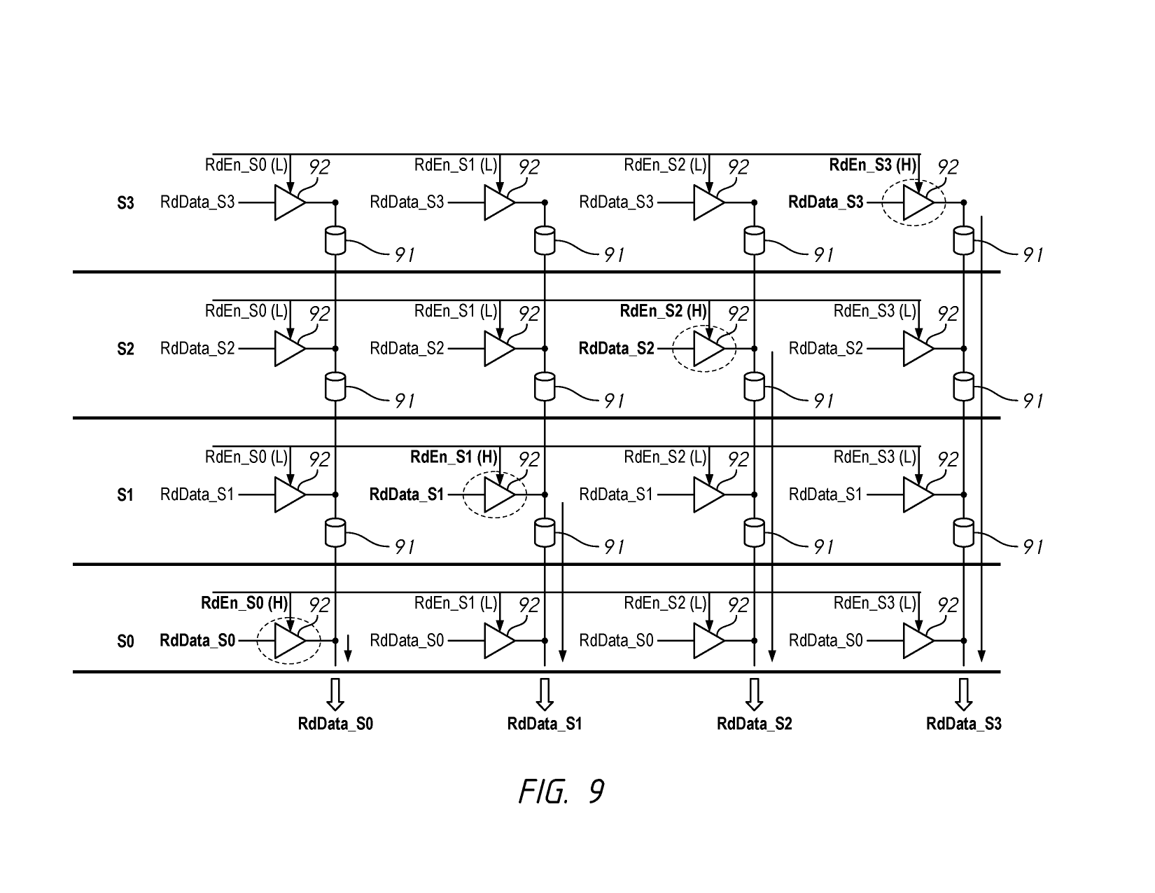

Subsequently, each of the stacked slices S0-S3 drives a state transition in TSV assigned thereto in response to RdCmd_Cal (504 in FIG. 5). FIG. 9 is a schematic diagram of example TSV allocation according to some embodiments of the disclosure. Triggered by RdCmd_Cal (see FIG. 6), one or more TSVs 91 are assigned to the respective slices and driven for transmission of the read data RdData_S0-S3. As shown in FIG. 9, data output buffers 92 are coupled to the respective TSVs 91 or TSV data paths in each slice, and are selectively driven by enable signals RdEn_S0-S3 that are in a high state (H) to provide RdData_S0-S3 to the assigned TSVs. The output data buffers 92 and hence the TSVs 91 are selectively driven to avoid data transfer conflict among the stacked slices S0-S3. As shown in FIG. 6, during the first RdRdy, all RdData_S0-S3 output from the assigned TSVs of slices S0-S3 transition from a first state to a second state. During the second RdRdy, all RdData_S0-S3 transition from the second state back to the first state. In the illustrated example, the first state is high (H), and the second state is low (L). In other instances, the first and second states may be low (L) and high (H), respectively. In either case, the timings of the transition may vary as shown in FIG. 6. By comparing the state transitions of RdData_S0-S3, the slowest RdData, that is the slice having the slowest read timing, can be determined. In the illustrated example, RdData_S0 turns high at the slowest timing among RdData_S0-S3. Then, by adding an appropriate delay to a signal, such as the read enable signal RdEn (see FIG. 4), that triggers the data reading at the other slices than the slowest slice, the data read timings of all slices are aligned to the slowest data read timing.

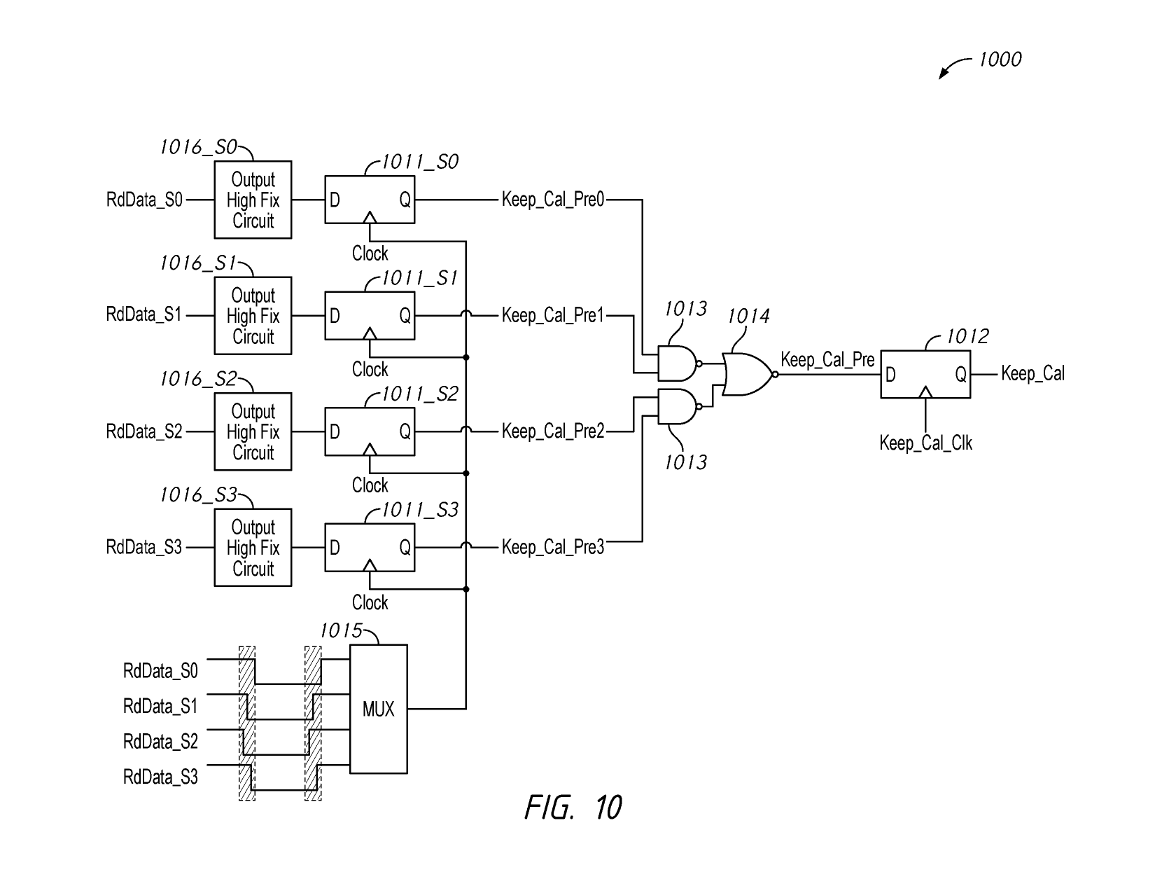

More specifically, as a first step, the state transitions of RdData output from the assigned TSVs of all slices S0-S3 are compared to determine the slowest slice (505 in FIG. 5). This is performed when a delay amount control signal RdCal_Trim<4:0> is at a default status 00000 (see FIG. 6). RdCal_Trim<4:0> (five bits as one example) may be generated at least in response to RdCal_En and/or RdCmd_Cal. RdCal_Trim<4:0> controls (or trims) an amount of a delay. RdCal_Trim<4:0> at the default status 00000 indicates that the amount of the delay is zero. No delay is added during the default status of RdCal_Trim<4:0>. FIG. 10 is a schematic diagram of at least part of an example apparatus 1000 according to some embodiments of the disclosure. The apparatus 1000 may include a comparison circuit, which may include at least a plurality of flip-flop circuits 1011_S0-S3 on an input side and another flip-flop circuit 1012 on an output side. The flip-flop circuits 1011_S0-S3 receive RdData_S0-S3 of slice S0-S3 as data signals and as clock signals. In the depicted example, RdData_S0-S3 may be provided to the flip-flop circuits 1011_S0-S3 through a multiplexer (MUX) 1015. The multiplexer 1015 selects RdData according to slice IDs. For example, for slice S0, the multiplexer 1015 selects RdData_S0 and forwards it to the flip-flop circuits 1011_S0-S3 as clock signals. For slice S2, the multiplexer 1015 selects RdData_S2 and forwards it to the flip-flop circuits 1011_S0-S3 as clock signals. Furthermore, in the depicted example, output high fix circuits 1016_S0-S3 may be provided on the respective input paths of RdData_S0-S3 to the flip-flop circuits 1011_S0-S3. The output high fix circuits 1016_S0-S3 may fix output signals high according to slice IDs. For example, in the case of slice S0 where RdData_S0 is used as the clock signals, the output high fix circuit 1016_S0 fixes RdData_S0 high and outputs it to the flip-flop circuit 1011_S0. In the case of slice S2 where RdData_S2 is used as the clock signals, the output high fix circuit 1016_S2 fixes RdData_S2 high and outputs it to the flip-flop circuit 1011_S2 as the data signal. The output high fix circuits 1016_S0-S3 each may include some logical gates as appropriate. The configuration of the output high fix circuits 1016_S0-S3 is not limited so long as the above function is achieved.

In response to the data signals and the clock signals, the flip-flop circuits 1011_S0-S3 output calibration control signals Keep_Calibration_Pre0-3 (or Keep_Cal_Pre0-3). For example, starting with slice S0 as a current slice designated by RdCmd_Cal, RdData_S0 selected by the multiplexer 1015 is driven to each of the flip-flop circuits 1011_S0-S3 as the clock signal while RdData_S0-S3 are input to the corresponding flip-flop circuits 1011_S0-S3. When RdData_S0 transitions to high at its rising edge, RdData_S1-S3 are already in the high state (see FIG. 6). Therefore, while RdData_S0 is fixed high by the output high fix circuit 1016_S0, which causes the output signal Keep_Cal_Pre0 of the flip-flop circuit 1011_S0 high, all output signals Keep_Cal_Prep1-3 of the flip-flop circuits 1011_S1-S3 also become high. Keep_Cal_Prep0-3 in the high state pass through some logic gates, such as NAND and NOR gates 1013 and 1014 and/or other gates as appropriate, which generate another calibration control signal Keep_Calibration_Pre (or Keep_Cal_Pre) reflecting the statuses of Keep_Cal_Prep0-3. Then, Keep_Cal_Pre in the high state is input to the next flip-flop circuit 1012. The flip-flop circuit 1012 receives a clock signal Keep_Calibration_Clk (or Keep_Cal_Clk). Keep_Cal_Clk may be generated at least in response to another clock signal Trim_Count_Clk. Trim_Count_Clk may be generated at least every other RdRdy. In FIG. 6, Keep_Cal_Clk is generated at the second Trim_Count_Clk which is synced with the third RdRdy. The flip-flop circuit 1012 generates another calibration control signal Keep_Calibration (or Keep_Cal) at least in response to Keep_Cal_Pre and Keep_Cal-Clk. Keep_Cal transitions to high at the Keep_Cal_Clk timing. Keep_Cal in the high state indicates that the current slice S0 has the slowest data read timing among slices S0-S3, and causes RdCal_Trim<4:0> to remain at the default/low state 00000 (see FIG. 6) for slice S0 during the calibration operation of the other slices. Hence, no delay will be added to the read enable signal RdEn_S0 of slice S0 (see FIG. 4), and the data read timing of slice S0 is maintained in the original state. Similar processes to the above are performed when the current slice is a different slice. When slice S1 is designated as the current slice by RdCmd_Cal, RdData_S1 is selected by the multiplexer 1015 and used as the clock signal of each of the flip-flop circuits 1011_S0-S3 while RdData_S0-S3 are input to the flip-flop circuits 1011_S0-S3, respectively. When RdData_S1 transitions to high, RdData_S2 is in the high state whereas RdData S0 and S3 are not (see FIG. 6). Therefore, while RdData_S1 is fixed high by the output high fix circuit 1016_S1, which causes the output signal Keep_Cal_Pre1 of the flip-flop circuit 1011_S1 high, Keep_Cal_Pre 2 becomes high whereas Keep_Cal_Pre0 and 3 stays low, which cause both Keep_Cal_Pre and Kee_Cal to be low. This indicates that slice S1 is not the slowest slice. The same result applies to slices S2 and S3 in the illustrated example of FIG. 6. Accordingly, slice S0 is determined as the slowest slice, and slices S2-3 becomes calibration-target slices.

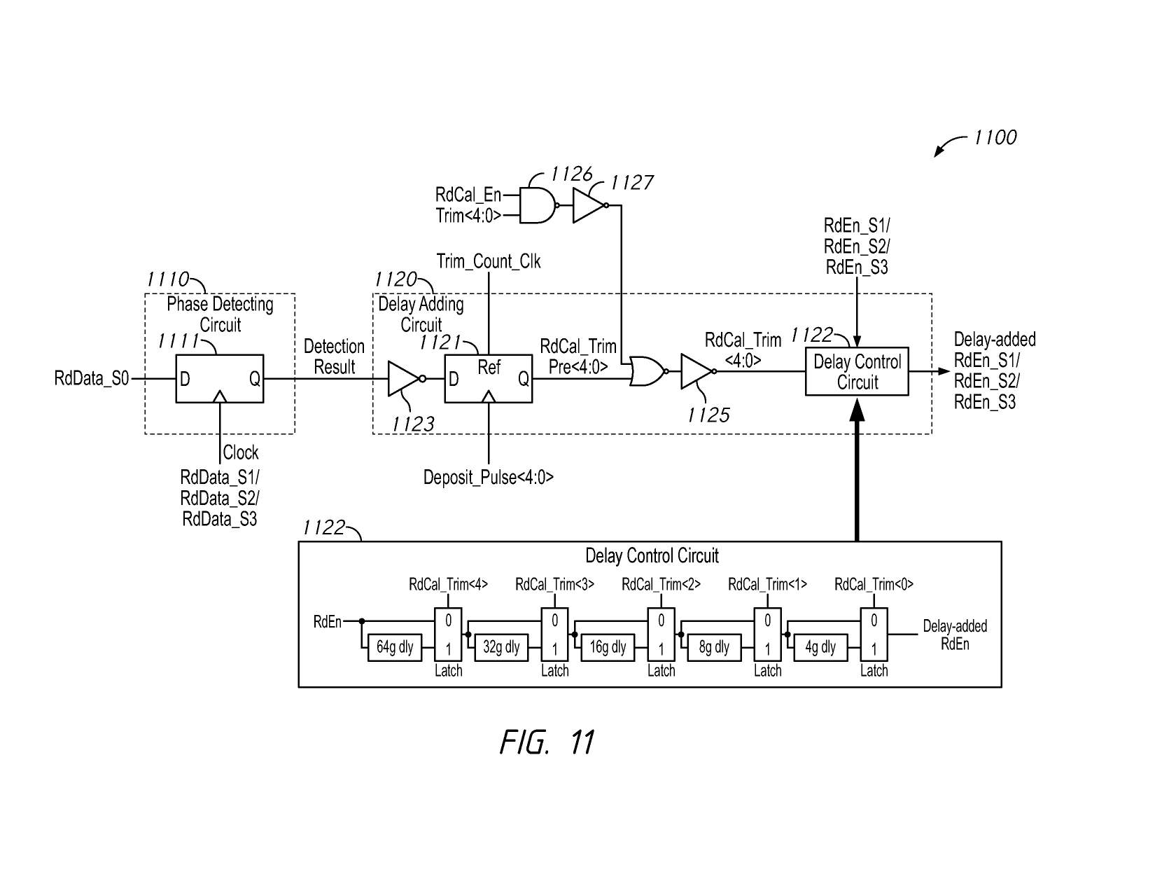

As a next step, a delay is added to each of the read enable signals RdEn_S1-S3 of calibration-target slices S1-S3 other than the slowest slice S0 (506 in FIG. 5). FIG. 11 is a schematic diagram of at least part of an example apparatus 1100 according to some embodiments of the disclosure. The apparatus 1100 may include at least a phase detecting circuit 1110 and a delay adding circuit 1120 coupled to the phase detecting circuit 1110. The phase detecting circuit 1110 may include at least a flip-flop circuit 1111 that receives the read data RdData_S0 of the slowest slice S0 as a data signal and receives, depending on which slice S1, S2, or S3 is the current target slice, the read data RdData_S1, S2, or S3 of slice S1, S2, or S3 as a clock signal for phase detection. As one example, FIG. 7 shows an example case where slice S2 is the current target slice designated by RdCmd_Cal. The flip-flop circuit 1111 outputs a result of the phase detection. The detection result signal is then input to the delay adding circuit 1120. The delay adding circuit 1120 may include at least a flip-flop circuit 1121 and a delay control circuit 1122 coupled to the flip-flop circuit 1121. The flip-flop circuit 1121 receives an output signal of the phase detecting circuit 1110 and outputs another delay amount control signal RdCal_Trim_Pre<4:0> (five bits as one example). The delay control circuit 1122 outputs a delay-added read enable signal RdEn_S1/S2/S3 at least in response to the delay amount control signals RdCal_Trim_Pre<4:0> and RdCal_Trim<4:0>. In the present embodiments, the flip-flop circuit 1121 may include five individual flip-flop circuits for signals of five bits as one example. In some embodiments, the phase detecting circuit 1110 may be part of the delay adding circuit 1120. At the delay adding circuit 1120, the flip-flop circuit 1121 receives the detection result signal as a data signal. The detection result signal may be provided to the flip-flop circuit 1121 through some logic gates, such as an inverter 1123 and/or other gates as appropriate. The flip-flop circuit 1121 also receives a pulse signal Deposit_Pulse<4:0> (five bits as one example) as a clock signal and Trim_Count_Clk as a reference signal, and provides RdCal_Trim_Pre<4:0>. As shown in FIG. 7, Deposit_Pulse may be generated at least in response to Trim_Count_Clk. Deposit_Pulse is synced with Trim_Count_Clk, and the first Deposit_Pulse<4> is generated at the third Trim_Count_Clk, the second Deposit_Pulse<3> is generated at the fourth Trim_Count_Clk, and so on. As described with respect to FIG. 6, Trim_Count_Clk may be generated at least every other RdRdy. In FIG. 11, the delay adding circuit 1120 may further include a series-coupled NOR gate and inverter circuit 1124-1125 that outputs RdCal_Trim<4:0> from RdCal_Trim_Pre<4:0> in response to, for example, RdCal_En and another delay amount control signal Trim<4:0> (five bits as one example) supplied to the NOR gate 1124 through a series-coupled NAND gate and inverter circuit 1126-1127. In some instances, the circuit 1126-1127 may be part of the delay adding circuit 1120. The apparatus 1100 performs the calibration operation until the data read timing calibration mode RdCal_En is disabled. By the calibration operation, RdCal_Trim<4:0> is set to a value that corresponds to an appropriate delay amount of the read enable signal to cause the data read timing of the target slice to align with or at least closest to the data read timing of the slowest slice (507 in FIG. 5).

In the example case shown in FIG. 7, to start the calibration operation to determine the appropriate delay amount for slice S2, Trim<4:0> are first set to high 10000 from low 00000 by one bit at the falling edge of the second Trim_Count_Clk after the third RdRdy. Trim<4:0> may be generated at least in response to Trim_Count_Clk. Trim<4:0> changes its value every Trim_Count_Clk by one bit (10000, 01000, 00100, 00010, 00001), and at the end of RdCal_En, is reset to low 00000. The detection result signal in the low state from the flip-flop circuit 1111 of the phase detecting circuit 1110 that has received RdData_S2 of slice S2 as the clock signal and RdData_S0 of slice S0 as the data signal is first input to the delay adding circuit 1120. At the flip-flop circuit 1121 of the delay adding circuit 1120, RdCal_Trim_Pre<4:0> stays unchanged at its default value 00000 since Deposit_Pulse is not yet generated at this timing. In response to Trim <4:0>=10000 and RdCal_Trim_Pre<4:0>=00000, RdCal_Trim<4:0> is set to high 10000 from the default status 00000. In the present embodiments, RdCal_Trim<4:0> may determine the number of delay gate stages. For example, a RdCal_Trim<4> (10000) signal controls a 64-gate delay that is a delay generated by 64 gate stages, a RdCal_Trim<3> (01000) signal controls a 32-gate delay that is a delay generated by 32 gate stages, a RdCal_Trim<2> (01100) signal controls a 16-gate delay that is a delay generated by 16 gate stages, a RdCal_Trim<1> (01110) signal controls an 8-gate delay that is a delay generated by 8 gate stages, and a RdCal_Trim<0> (01101) signal controls a 4-gate delay that is a delay generated by 4 gate stages. The number of delay gate stages and the delay amounts are not limited to this example and may be determined as appropriate based on, for example, device specifications, designs, and the like.

At this first calibration timing, at the delay control circuit 1122 receiving RdCalTrim <4:0>=10000, a 64-gate delay is added to RdEn_S2, which in turn causes RdData_S2 to delay. In some instances, the 64-gate delay may be added to a signal path of RdEn_S2 of slice S2. As shown in FIG. 7, however, the 64-gate delay may delay RdData_S2 more than RdData_S0. The rising edge of RdData_S2 comes after the rising edge of RdData_S0. This means that the 64-gate delay is too long and cannot be used, and this result is stored (or deposited) in the latch (see FIG. 11) by enabling Deposite_Pulse<4> which is generated at the timing of the next Trim_Count_Clk, which also triggers the next (second) calibration timing.

At the second calibration timing, the value of Trim<4:0> is set to 01000. The phase detection result signal from the flip-flop circuit 1111 is in a high state because RdData_S2 is now slower than (and out of phase with) RdData_S0. In response to the phase detection result signal in high as well as Deposite_Pulse<4> and Trim_Count_Clk, the value (the first digit) of RdCal_Trim_Pre<4:0> is set to 00000 by one bit at the flip-flop circuit 1121. Then, in response to RdCal_Trim_Pre<4:0>=00000 and Trim<4:0>=01000, the value of RdCal_Trim<4:0> changes to 01000 from 10000, and at the delay control circuit 1122, in response to RdCal_Trim<4:0>=01000, a 32-gate delay is added to RdEn_S2. This time, RdData_S2 may be adjusted to have its timing ahead of RdData_S0 but closer to RdData_S0 than before the calibration started. The rising edge of RdData_S2 comes before but slightly closer to the rising edge of RdData_S0. The 32-gate delay is thus stored in the latch by enabling Deposite_Pulse<3> which is generated at the timing of the next Trim_Count_Clk, which also triggers the next (third) calibration timing.

At the third calibration timing, the value of Trim<4:0> is set to 00100. The phase detection result signal from the flip-flop circuit 1111 turns back to the low state because RdData_S2 is now faster than (and still out of phase with) RdData_S0. In response to the phase detection result in low, Deposite_Pulse<3> and Trim_Count_Clk, the value of RdCal_Trim_Pre<4:0> is set to 01000 from 00000 by one bit at the flip-flop circuit 1121. Then, in response to RdCal_Trim_Pre<4:0>=01000 and Trim<4:0>=00100, the value of RdCal_Trim<4:0> changes to 01100 from 01000. This time, because the 32-gate delay has been saved in the latch by Deposite_Pulse<3>, a 16-gate delay is added to RdEn_S2 in addition to the 32-gate delay at the delay control circuit 1122 in response to RdCal_Trim<4:0>=01100. This causes RdData_S2 to rise and fall at substantially the same timing as or within a tolerable range from RdData_S0. Therefore, the 32+16-gate delay are stored in the latch by enabling Deposite_Pulse<2> which is generated at the timing of the next Trim_Count_Clk, which also triggers the next (fourth) calibration timing.

At the fourth calibration timing, the value of Trim<4:0> is set to 00010. The phase detection result signal from the flip-flop circuit 1111 stays low because RdData_S2 is in phase with RdData_S0. In response to the phase detection result in low, Deposite_Pulse<2> and Trim_Count_Clk, the value of RdCal_Trim_Pre<4:0> is set to 01100 from 01000 by one bit at the flip-flop circuit 1121. Then, in response to RdCal_Trim_Pre<4:0>=01100 and Trim<4:0>=00010, the value of RdCal_Trim<4:0> changes to 01110 from 01100. This time, because the 32+16 gate delay has been saved in the latch by Deposite_Pulse<2>, an 8-gate delay is added to RdEn_S2 in addition to the 32+16 gate delay at the delay control circuit 1122 in response to RdCal_Trim<4:0>=01110. This causes RdData_S2 to rise a little after RdData_S0 but fall at substantially the same timing as RdData_S0. Therefore, the 32+16+8 gate delay are stored in the latch by enabling Deposite_Pulse<1> which is generated at the timing of the next Trim_Count_Clk, which also triggers the next (fifth) calibration timing.

Finally, at the fifth calibration timing before RdCal_En is disabled, the value of Trim<4:0> is set to 00001. The phase detection result signal from the flip-flop circuit 1111 is now in the high state because the rising edge of RdData_S2 is slightly slower than that of RdData_S0. In response to the phase detection result in high, Deposite_Pulse<2> and Trim_Count_Clk, the value of RdCal_Trim_Pre<4:0> is set to 01100 from 01100 by one bit at the flip-flop circuit 1121. Then, in response to RdCal_Trim_Pre<4:0>=01100 and Trim<4:0>=00001, the value of RdCal_Trim<4:0> changes to 01101 from 01110. This time, because the 32+16+8 gate delay has been saved in the latch by Deposite_Pulse<1>, a 4-gate delay is added to RdEn_S2 in addition to the 32+16+8 gate delay at the delay control circuit 1122 in response to RdCal_Trim<4:0>=01101. This causes RdData_S2 to rise closer to RdData_S0 than the previous calibration timing while keeping the falling edge of RdData_S2 at substantially the same timing as the falling edge of RdData_S0. Therefore, the 32+16+8+4-gate delay (which is less than the 64-gate delay in total) are stored in the latch by enabling Deposite_Pulse<0> which is generated at the next Trim_Count_Clk. RdCal_En is then disabled.

This way, the calibration operation can determine the appropriate delay amount for slice S2, causing the data read timing to align with the data read timing of slice S0 as close as possible. The calibration operation is repeated for the other target slices S1 and S3 in a similar manner. Consequently, the data read timings match between all stacked slices (507 in FIG. 5).

In the present embodiments, a delay is added to the read enable signal RdEn of each calibration-target slice. In other embodiments, a delay may be added to the read command for calibration RdCmd_Cal of each calibration-target slice because the RdCmd_Cal signal is a source signal of the RdEn signal.

DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the semiconductor memory device 1101. Furthermore, devices other than memory, including logic ICs, such as a microprocessor and an application-specific integrated circuit (ASIC), are also applicable as the semiconductor device according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a plurality of through-silicon vias (TSVs);
a plurality of core dies stacked with one another, each core die configured to output read data to one or more assigned TSVs of the plurality of TSVs in response to a read enable signal; and
a calibration circuit configured to:
compare data read timings of the core dies to determine a slowest core die; and
add a delay to the read enable signal of at least one of the core dies other than the slowest core die to cause the data read timing of the at least one of the core dies match the data read timing of the slowest core die.

2. The apparatus according to claim 1, wherein the calibration circuit compares state transitions of the read data of the respective core dies to compare the data read timings.

3. The apparatus according to claim 2, wherein the state transitions include a transition from a first state to a second state, and the first state is one of a high state and a low state, and the second state is another of the high state and the low state.

4. The apparatus according to claim 1, wherein the calibration circuit comprises one or more flip-flop circuits configured to receive the read data from the respective core dies as data signals and as clock signals and output a calibration control signal to keep the read timing of the slowest core die uncalibrated.

5. The apparatus according to claim 1, wherein the calibration circuit comprises:
a plurality of first flip-flop circuits configured to receive the read data from corresponding core dies of the plurality of core dies as first data signals, receive the read data from at least one core die selected from the plurality of core dies as a first clock signal, and output first calibration control signals; and
a second flip-flop circuit configured to receive the first calibration control signals as a second data signal, receive a second clock signal, and output a second calibration control signal to indicate the slowest core die.

6. The apparatus according to claim 5, wherein if all of the first calibration control signals output from the first flip-flop circuits are in a high state, the second calibration control signal from the second flip-flop circuit indicates that the selected core die is the slowest core die.

7. The apparatus according to claim 1, wherein
the at least one of the core dies other than the slowest core die is a calibration-target core die, and
the calibration circuit comprises:
a phase detecting circuit configured to receive the read data from the slowest core die as a data signal, receive the read data from the calibration-target core die as a clock signal, and output a phase detection result; and
a delay adding circuit configured to add the delay to the read enable signal of the calibration-target core die in response to the phase detection result.

8. The apparatus according to claim 7, wherein the delay adding circuit calibrates an amount of the delay in response to a delay amount control signal, the delay amount control signal changes a value thereof at every calibration timing and controls the amount of the delay.

9. The apparatus according to claim 7, wherein the calibration timing is repeatedly set in response to a clock signal generated in response to a read command for calibration until the read enable signal is disabled.

10. The apparatus according to claim 1, wherein the plurality of core dies each comprise a data output circuit coupled to at least one of the assigned TSVs to output the read data in response to the read enable signal.

11. The apparatus according to claim 1, wherein
a bottom core die of the stacked core dies is a master chip configured to receive a read command for calibration from external devices, and upper core dies are slave chips configured to receive the read command from the master chip through the TSVs, the read command triggers the read enable signal, and
the read command for calibration is used to generate the read enable signal.

12. The apparatus according to claim 1, wherein
a bottom core die of the stacked core dies is an interface die configured to receive a read command for calibration from external devices, and upper core dies are configured to receive the read command from the master chip through the TSVs, and
the read command is used to generate the read enable signal.

13. An apparatus, comprising:
a plurality of through-silicon vias (TSVs);
a plurality of core dies stacked with one another, each core die configured to output read data to one or more assigned TSVs of the plurality of TSVs in response to a read enable signal; and
a calibration circuit configured to:
compare data read timings of the core dies to determine a slowest core die; and
add a delay to the read enable signal of at least one of the core dies other than the slowest core die to cause the data read timing of the at least one of the core dies match the data read timing of the slowest core die, wherein
the calibration circuit includes:
a plurality of first flip-flop circuits configured to receive the read data from corresponding core dies of the plurality of core dies as first data signals, receive the read data from at least one core die selected from the plurality of core dies as a first clock signal, and output first calibration control signals; and
a second flip-flop circuit configured to receive the first calibration control signals as a second data signal, receive a second clock signal, and output a second calibration control signal to indicate the slowest core die, and
if all of the first calibration control signals output from the first flip-flop circuits are in a high state, the second calibration control signal from the second flip-flop circuit indicates that the selected core die is the slowest core die.

14. The apparatus according to claim 13, wherein the calibration circuit compares state transitions of the read data of the respective core dies to compare the data read timings, the state transitions include a transition from a first state to a second state, and the first state is one of a high state and a low state, and the second state is another of the high state and the low state.

15. The apparatus according to claim 13, wherein
the at least one of the core dies other than the slowest core die is a calibration-target core die, and
the calibration circuit comprises:
a phase detecting circuit configured to receive the read data from the slowest core die as a data signal, receive the read data from the calibration-target core die as a clock signal, and output a phase detection result; and
a delay adding circuit configured to add a delay to the read enable signal of the calibration-target core die in response to the phase detection result.

16. The apparatus according to claim 15, wherein the delay adding circuit calibrates an amount the delay in response to a delay amount control signal, the delay amount control signal changes a value thereof at every calibration timing and controls the amount of the delay.

17. An apparatus, comprising:
a plurality of through-silicon vias (TSVs);
a plurality of core dies stacked with one another, each core die configured to output read data to one or more assigned TSVs of the plurality of TSVs in response to a read enable signal; and
a calibration circuit configured to:
compare data read timings of the core dies to determine a slowest core die; and
add a delay to the read enable signal of at least one of the core dies other than the slowest core die to cause the data read timing of the at least one of the core dies match the data read timing of the slowest core die, wherein
the at least one of the core dies other than the slowest core die is a calibration-target core die, and
the calibration circuit includes:
a phase detecting circuit configured to receive the read data from the slowest core die as a data signal, receive the read data from the calibration-target core die as a clock signal, and output a phase detection result; and
a delay adding circuit configured to calibrate an amount of the delay in response to the phase detection result and a delay amount control signal, the delay amount control signal changing a value thereof at every calibration timing, and to add the delay of the calibrated amount to the read enable signal of the calibration-target core die.

18. The apparatus according to claim 17, wherein the calibration timing is repeatedly set in response to a clock signal generated in response to a read command for calibration until the read enable signal is disabled.

19. The apparatus according to claim 17, wherein the calibration circuit compares state transitions of the read data of the respective core dies to compare the data read timings, the state transitions include a transition from a first state to a second state, and the first state is one of a high state and a low state, and the second state is another of the high state and the low state.

20. The apparatus according to claim 17, wherein the calibration circuit comprises:
a plurality of first flip-flop circuits configured to receive the read data from corresponding core dies of the plurality of core dies as first data signals, receive the read data from at least one core die selected from the plurality of core dies as a first clock signal, and output first calibration control signals; and
a second flip-flop circuit configured to receive the first calibration control signals as a second data signal, receive a second clock signal, and output a second calibration control signal to indicate the slowest core die, and
if all of the first calibration control signals output from the first flip-flop circuits are in a high state, the second calibration control signal from the second flip-flop circuit indicates that the selected core die is the slowest core die.
